(19) United States
(12) Patent Application Publication
(10) Pub. No.: US 2025/0379182 A1
(43) Pub. Date: Dec. 11, 2025

(54) DIE BONDING APPARATUS

(71) Applicant: SAMSUNG ELECTRONICS CO., LTD., Suwon-si (KR)

(72) Inventor: Boseok KWON, Suwon-si (KR)

(73) Assignee: SAMSUNG ELECTRONICS CO., LTD., Suwon-si (KR)

(21) Appl. No.: 19/098,579

(22) Filed: Apr. 2, 2025

(30) Foreign Application Priority Data
Jun. 7, 2024 (KR) 10-2024-0074349

(51) Int. Cl. H01L 23/00

(52) U.S. Cl. CPC H01L 24/75; H01L 2224/7501; H01L 2224/75251; H01L 2224/7565; H01L 2224/75753; H01L 2224/75841; H01L 2224/75901

(57) ABSTRACT

A die bonding apparatus includes a head guide extending in a horizontal direction between a first position and a second position, the head guide including an orbital transfer route including a supply path from the first position to the second position and a return path from the second position to the first position, and a die transfer device configured to move along the orbital transfer route of the head guide, the die transfer device including at least one pick-up head configured to pick up a die at the first position and to attach the die on a target object at the second position.

### CROSS-REFERENCE TO RELATED APPLICATIONS

This application is based on and claims priority to Korean Patent Application No. 10-2024-0074349, filed on Jun. 7, 2024, in the Korean Intellectual Property Office (KIPO), the disclosure of which is incorporated by reference herein in its entirety.

### BACKGROUND

The present disclosure relates to a die bonding apparatus, and more particularly, a die bonding apparatus for attaching a die individualized from a wafer to a substrate or another die.

A die bonding process may include a pick-up operation of vacuum-transferring a die on a ring frame structure and an attach operation of attaching the die to a substrate. However, when the pick-up operation and the attach operation are performed as two operations by using different heads, a large amount of process time may be consumed and accuracy of process may be deteriorated. Further, when the pick-up operation and the attach operation are performed by using a single head, the accuracy of the process may be deteriorated because the head is moved in multiple directions.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public,

### SUMMARY

One or more example embodiments provide a die bonding apparatus that may be capable of minimizing head distortion and reducing process time.

Additional aspects will be set forth in part in the description which follows and, in part, will be apparent from the description, or may be learned by practice of the presented embodiments.

According to an aspect of an example embodiment, a die bonding apparatus may include a head guide extending in a horizontal direction between a first position and a second position, the head guide including an orbital transfer route including a supply path from the first position to the second position and a return path from the second position to the first position, and a die transfer device configured to move along the orbital transfer route of the head guide, the die transfer device including at least one pick-up head configured to pick up a die at the first position and to attach the die on a target object at the second position.

According to an aspect of an example embodiment, a die bonding apparatus may include a die support device at a first position and configured to provide a die, a die attachment device at a second position spaced apart from the first position along a horizontal direction and configured to attach the die on a target object, and a head module including a head guide horizontally extending between the first position and the second position and a die transfer device including a plurality of pick-up heads configured to move along the head guide, where the head guide includes an orbital transfer route including a supply path from the first position to the second position and a return path from the second position to the first position, and the plurality of pick-up heads are spaced apart from each other and each of the plurality of pick-up heads is configured to be individually movable along the transfer route of the head guide.

According to an aspect of an example embodiment, a die bonding apparatus may include a die support device at a first position and configured to provide a die, a die attachment device at a second position spaced apart from the first position along a horizontal direction and configured to attach the die on a target object, a head guide extending in the horizontal direction between the first position and the second position, the head guide including an orbital transfer route including a supply path from the first position to the second position and a return path from the second position to the first position, and a die transfer device configured to move along the transfer route of the head guide, the die transfer device including at least one pick-up head configured to pick up a die at the first position and to attach the die on the target object at the second position, where the head guide may include a rail including a supply rail portion providing the supply path, a return rail portion providing the return path, a pick-up rail portion above the die support device, the pick-up rail portion providing a first vertical movement path extending in a vertical direction for the at least one pick-up head to pick up the die, and an attach rail portion above the die attachment device, the attach rail portion providing a second vertical movement path extending in the vertical direction for the at least one pick-up head to attach the die.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a plan view illustrating a die bonding apparatus according to one or more embodiments.

FIG. 2 is a cross-sectional view illustrating a die support device according to one or more embodiments.

FIG. 3 is a cross-sectional view illustrating a die attachment device according to one or more embodiments.

FIG. 4 is a cross-sectional view illustrating a pick-up head according to one or more embodiments.

FIG. 5 is a perspective view illustrating the pick-up head according to one or more embodiments.

FIGS. 6 to 16 are views illustrating a method of bonding a die according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

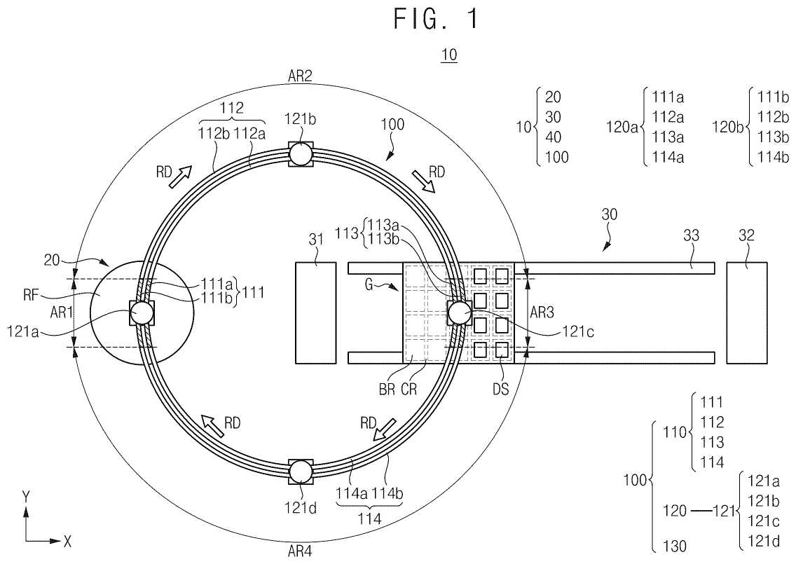

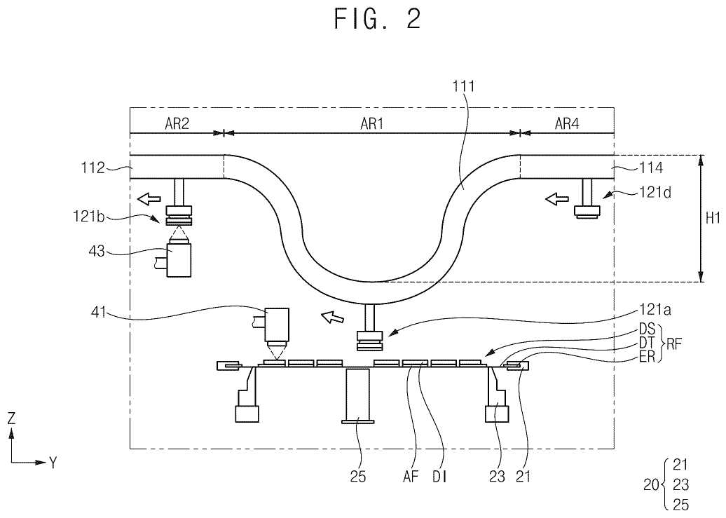

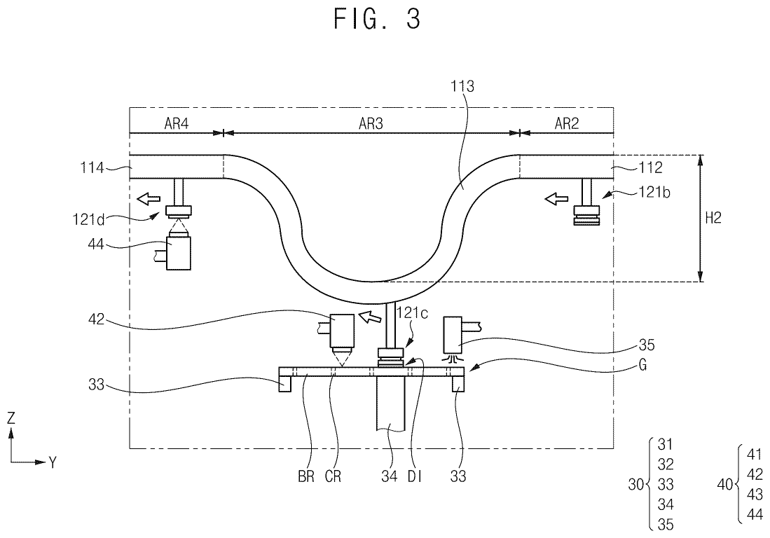

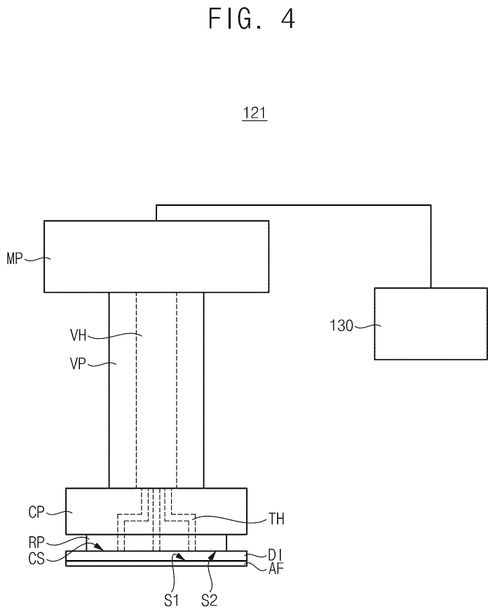

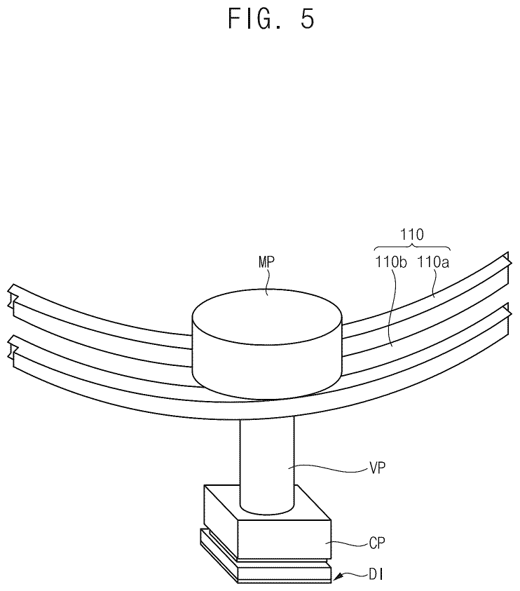

FIG. 1 is a plan view illustrating a die bonding apparatus according to one or more embodiments. FIG. 2 is a cross-sectional view illustrating a die support device according to one or more embodiments. FIG. 3 is a cross-sectional view illustrating a die attachment device according to one or more embodiments. FIG. 4 is a cross-sectional view illustrating a pick-up head according to one or more embodiments. FIG. 5 is a perspective view illustrating the pick-up head according to one or more embodiments.

Referring to FIGS. 1 to 5, a die bonding apparatus 10 may include a die support device 20 configured to supply a die which is diced from a wafer, a die attachment device 30 configured to attach the die on a target object G, and a head module 100 configured to transfer the die from the die support device 20 to the die attachment device 30. Additionally, the die bonding apparatus 10 may further include an imaging device 40 including a plurality of cameras.

In particular, the die bonding apparatus 10 may include a first position AR1, a second position AR2, a third position AR3, and a fourth position AR4 sequentially arranged along a clockwise direction to form an orbit (e.g., a circular orbit as shown in FIG. 1, but embodiments are not limited thereto, and the orbit may be elliptical, quadrilateral, and other shapes/configurations as will be understood by one of ordinary skill in the art from the disclosure herein). For example, the first position AR1 may be a region for providing the die, and the third position AR3 may be a region for attaching the die.

In one or more embodiments, the head module 100 may include a head guide 110 that is disposed horizontally between the first position AR1 and the third position AR3 and provides a transfer route in the orbit, and a die transfer device 120 that is movable along the transfer route of the head guide 110. The head module 100 may further include a controller 130 that is configured to control a movement of the die transfer device 120.

The head guide 110 may provide a supply path from the first position AR1 to the third position AR3 and a return path from the third position AR3 to the first position AR1.

The die transfer device 120 may include at least one pick-up head 121 that is movable along the transfer route of the head guide 110 and is configured to pick up the die at the first position AR1 and attach the die to the target object G at the third position AR3. For example, the at least one pick-up head 121 may have an upper portion including a movement device MP and a vertical extension device VP, and a lower portion including an transfer mechanism CP and cushioning portion RP. The lower portion may have a contact surface CS. The at least one pick-up head 121 may receive the die in the first position AR1 and secure the die to the contact surface CS of the lower portion of the pick-up head 121. Additionally, the at least one pickup head 121 may move the die from the first position AR1 to the third position AR3 along the head guide 110 so that the die reaches the target object G. Further, the at least one pickup head 121 may adjust a pressure applied to the die to attach the die to the target object G.

In one or more embodiments, the die support device 20 may be disposed at the first position AR1 and may be configured to provide an individualized die. That is, the die support device 20 may be configured as an expansion/extension device that receives a ring frame structure RF including a plurality of dies DS, and then expands/extends the ring frame structure RF to separate the individual dies DS such that the individual dies may be extracted and transferred to the die attachment device 30. In one or more embodiments, the die support device 20 may simply be configured to support a plurality of dies that have already been separated from a wafer.

The die support device 20 may include a clamp 21 configured to clamp a ring frame structure RF supporting a wafer including a diced die, a support ring 23 configured to expand the ring frame structure RF, and a lift supporting mechanism 25 configured to support the die to be transferred (i.e., received by the pick-up head 121). For example, the die support device 20 may be an apparatus configured to support a wafer including a plurality of dies DS and to separate the dies DS from the ring frame structure RF.

The ring frame structure RF may include a dicing tape DT having elasticity to be expandable in a horizontal direction, a plurality of dies DS provided on the dicing tape DT, and an expansion ring ER fixed to an edge region of the dicing tape DT. For example, the ring frame structure RF may be a structure configured to move and process the plurality of dies DS at once.

Each of the plurality of dies DS may include a die substrate DI and an adhesive film AF disposed between the die substrate DI and the dicing tape DT. The die substrate DI may have a front surface S1 and a backside surface S2 that face each other. For example, the front surface S1 may be an active surface on which electronic elements are formed, and the backside surface S2 may be an inactive surface. For example, the adhesive film AF may include a die attach film DAF. For example, the dies DS may include semiconductor chips to be mounted within a semiconductor package.

For example, the clamp 21 may be integrally coupled with the expansion ring ER of the ring frame structure RF. The clamp 21 may fix the expansion ring ER and the support ring 23 may be raised to expand the dicing tape DT in a horizontal direction. The wafer may be expanded along with the dicing tape DT and individualized into a plurality of dies DS.

The lift supporting mechanism 25 may be positioned under the ring frame structure RF. The lift supporting mechanism 25 may include a plurality of lift pins. The plurality of lift pins may be movable in a vertical direction. For example, the lift supporting mechanism 25 may be an apparatus configured to move each of the plurality of dies DS provided on the dicing tape DT in the vertical direction, thereby assisting in separating each of the plurality of dies DS from the dicing tape DT.

In one or more embodiments, the die attachment device 30 may be disposed at the third position AR3 spaced apart in the horizontal direction from the first position AR1 and may be configured to attach the die, which is provided from the die support device 20, to a target object G.

For example, the target object G may be a substrate for mounting a semiconductor device. The substrate may include a plurality of bonding regions BR and a cutting region CR surrounding the plurality of bonding regions BR. For example, the bonding region BR may be a region onto which the die is attached. The bonding region BR may be a region individualized into a semiconductor package by removing the cutting region CR through a dicing process. Alternatively, the target object G may be another die. The die may be attached to another die to form a stacked die structure.

The die attachment device 30 may include a loader 31 configured to supply the target object G, an unloader 32 configured to retrieve the target object G, and a substrate transfer mechanism 33 configured to move the target object G from the loader 31 to the unloader 32 in the horizontal direction. Additionally, the die attachment device 30 may further include a heating apparatus 34 and a foreign substance removal apparatus 35. For example, the die attachment device 30 may be an apparatus configured to attach a plurality of dies DS onto the target object G.

The substrate transfer mechanism 33 may be disposed under the target object G and extend in a first horizontal direction (X direction). For example, the loader 31, the substrate transfer mechanism 33 and the unloader 32 may be sequentially arranged along the first horizontal direction (X direction).

The substrate transfer mechanism 33 may contact the target object G and move the target object G in the first horizontal direction (X direction). The substrate transfer mechanism 33 may control a movement of the target object G in the first horizontal direction (X direction). For example, the substrate transfer mechanism 33 may stop the target object G when the die attaching process is in progress and move the target object G when the die attaching process is completed.

The heating apparatus 34 may be positioned under the target object G. The heating apparatus 34 may contact a lower surface of the target object G to heat the target object G when the die attaching process is in progress. The heating apparatus 34 may apply heat to the adhesive film AF provided between the die substrate DI and the target object G, thereby assisting in attaching the die substrate DI to the target object G.

The foreign substance removal apparatus 35 may be positioned above the target object G. For example, the foreign substance removal apparatus 35 may inject air onto the target object G to remove foreign substances before beginning the die attaching process.

In one or more embodiments, the imaging device 40 may include a first camera 41 provided at the first position AR1 and a second camera 42 provided at the third position AR3. Additionally, the imaging device 40 may include a third camera 43 provided at the second position AR2 and a fourth camera 44 provided at the fourth position AR4.

For example, the first camera 41 may be positioned above the ring frame structure RF and configured to capture images of the ring frame structure RF. Accordingly, the first camera 41 may check whether cracks have occurred in the plurality of dies DS. Additionally, the second camera 42 may be positioned above the target object G and configured to capture images of the target object G. Accordingly, the second camera 42 may be configured to inspect circuit patterns of the substrate G. Furthermore, the third camera 43 and the fourth camera 44 may be positioned under the head guide 110 and configured to capture images of at least one pick-up head 121.

Hereinafter, the head module 100 will be described in detail.

Referring again to FIGS. 1 to 5, the head module 100 may include a head guide 110 arranged horizontally between the first position AR1 and the third position AR3 to provide a transfer route and a die transfer device 120 movable along the transfer route of the head guide 110. The die transfer device 120 may include at least one pick-up head 121 movable along the transfer route of the head guide 110 to pick up the die at the first position AR1 and attach the die to the target object G at the third position AR3. Additionally, the head module 100 may further include a controller 130 configured to control the at least one pick-up head 121.

In one or more embodiments, the head guide 110 may be a rail that includes a plurality of portions. That is, the head guide 110 may include a rail having a pick-up rail portion 111, a supply rail portion 112, an attach rail portion 113, and a return rail portion 114 sequentially connected.

The supply rail portion 112 of the head guide 110 may provide a supply path from the first position AR1 to the second position AR3, and the return rail portion 114 of the head guide 110 may provide a return path from the second position AR3 to the first position AR1. Accordingly, the head guide 110 may provide a transfer route in an orbit (e.g., an infinite loop). For example, the pick-up rail portion 111, the supply rail portion 112, the attach rail portion 113, and the return rail portion 114 may sequentially connect to define a transfer route in an orbital loop.

The pick-up rail portion 111 may provide a first vertical path (e.g., may extend downward in a vertical direction with respect to the return rail portion 114 and the supply rail portion 112) for picking up dies from the die support device 20. For example, the pick-up rail portion 111 may be provided at the first position AR1 such that the pick-up rail portion is positioned above the die support device 20. The pick-up rail portion 111 may guide at least one pick-up head 121 to a region adjacent to the ring frame structure RF provided by the die support device 20. For example, the at least one pick-up head may function as a transfer head.

The supply rail portion 112 may provide the supply path of the transfer route. For example, the supply rail portion 112 may be provided at the second position AR2 to connect the first position AR1 and the third position AR3 in a horizontal direction. That is, the supply rail portion 112 may extend radially through the second position AR2 to connect the first position AR1 and the third position AR3 along the orbital trajectory of the transfer route. The supply rail portion 112 may guide at least one pick-up head 121 from the first position AR1 to the third position AR3.

The second camera 42 may be positioned under the supply rail portion 112. For example, the second camera 42 may capture images of the die, the die being attached to at least one pick-up head 121. The at least one pick-up head 121 may move along the supply rail portion 112.

The attach rail portion 113 may provide a second vertical path (e.g., may extend vertically downward with respect to the supply rail portion 112 and the return rail portion 114) for attaching a die to the die attachment device 30. For example, the attach rail portion 113 may be provided at the third position AR3 such that the attach rail portion 113 is positioned above the die attachment device 30. The attach rail portion 113 may guide at least one pick-up head 121 to a region adjacent to the target object G which is provided by the die attachment device 30. For example, the at least one pick-up head 121 may function as an attach head.

The return rail portion 114 may provide the return path of the transfer route. For example, the return rail portion 114 may be provided at the fourth position AR4 to connect the first position AR1 and the third position AR3 in a horizontal direction. That is, the return rail portion 114 may extend radially through the fourth position AR4 to connect the first position AR1 and the third position AR3 along the orbital trajectory of the transfer route. The return rail portion 114 may guide at least one pick-up head 121 from the third position AR3 to the first position AR1.

The fourth camera 44 may be positioned under the return rail portion 114. For example, the fourth camera 44 may capture images of at least one pick-up head 121. The at least one pick-up head 121 may move along the return rail portion 114.

The pick-up rail portion 111 and the attach rail portion 113 may respectively connect the supply rail portion 112 and the return rail portion 114. Each of the pick-up rail portion 111 and the attach rail portion 113 may be a portion protruding downward in a vertical direction from the supply rail portion 112 and the return rail portion 114. For example, the pick-up rail portion 111 may have a first vertical path protruding downward from the supply rail portion 112 and the return rail portion 114, the first vertical path having a semi-elliptical shape. Also, the attach rail portion 113 may have a second vertical path protruding downward from the supply rail portion 112 and the return rail portion 114, the second vertical path having a semi-elliptical shape (e.g., a parabolic shape).

For example, the pick-up rail portion 111 may extend to a first height H1 in a vertical direction from the supply rail portion 112 and the return rail portion 114. Additionally, the attach rail portion 113 may extend to a second height H2 in a vertical direction from the supply rail portion 112 and the return rail portion 114. The first height H1 and the second height H2 may be substantially the same or may differ depending on the construction and position of other components of the apparatus 10.

The head guide 110 may include at least one rail having an orbit when in plan view such that the at least one rail is at least partially positioned at the first position AR1 and the third position AR3.

For example, the head guide 110 may include a first rail 120a and second rail 120b, the first rail 120a and the second rail 120b having a circular orbit in plan view. For example, the first rail 120a and the second rail 120b may have a concentric circular shape such that the first rail 120a and the second rail 120b have centers matching with each other in plan view.

The first rail 120a may include a first portion 111a of the pick-up rail portion 111, a first portion 112a of the supply rail portion 112, a first portion 113a of the attach rail portion 113, and a first portion 114a of the return rail portion 114. Additionally, the second rail 120b may include a second portion 111b of the pick-up rail portion 111, a second portion 112b of the supply rail portion 112, a second portion 113b of the attach rail portion 113, and a second portion 114b of the return rail portion 114.

In one or more embodiments, at least one pick-up head 121 of the die transfer device 120 may include first to fourth pick-up heads 121a, 121b, 121c, and 121d that are spaced apart from each other in a horizontal direction and along the orbital direction of the transfer route. Each of the first to fourth pick-up heads 121a, 121b, 121c, and 121d may function as a transfer head and an attach head. For example, the transfer head may be configured to separate a die from the ring frame structure RF and transfer the die to a substrate. The attach head may be configured to position the die on the substrate and apply pressure to attach the die to the substrate.

Each of the first to fourth pick-up heads 121a, 121b, 121c, and 121d may sequentially move along the transfer route of the head guide 110 and perform the roles of the transfer head and the attach head. For example, each of the first to fourth pick-up heads 121a, 121b, 121c, and 121d may individually move along the transfer route of the head guide 110.

For example, each of the first to fourth pick-up heads 121a, 121b, 121c, and 121d may move along the pick-up rail portion 111 to a region adjacent to the ring frame structure RF on the die support device 20 Each of the first to fourth pick-up heads 121a, 121b, 121c, and 121d may pick up a die from the ring frame structure RF at the first position AR1.

Each of the first to fourth pick-up heads 121a, 121b, 121c, and 121d may move along the supply rail portion 112 from the first position AR1 to the third position AR3. Each of the first to fourth pick-up heads 121a, 121b, 121c, and 121d at the second position AR2 may secure the die to a lower portion of each of the first to fourth pick-up heads 121a, 121b, 121c, and 121d, and each of the first to fourth pick-up heads 121a, 121b, 121c, and 121d may transport the die, although the dies may be secured at any position between AR1 and AR3.

Each of the first to fourth pick-up heads 121a, 121b, 121c, and 121d may move along the attach rail portion 113 to a region adjacent to the target object G on the die attachment device 30. Each of the first to fourth pick-up heads 121a, 121b, 121c, and 121d may deposit the die to the target object G at the third position AR3.

Each of the first to fourth pick-up heads 121a, 121b, 121c, and 121d may move back along the return rail portion 114 from the third position AR3 to the first position AR1.

Referring again to FIG. 4, the pick-up head 121 may include a movement device MP for moving the pick-up head 121, a vertical extension device VP extending vertically from the movement device MP, and a transfer mechanism CP provided at one end portion of the vertical extension device VP.

The vertical extension device VP may include a through-hole VH connected to a hydraulic apparatus for generating pressure. Additionally, the vertical extension device VP may include a vertical moving apparatus capable of moving in the vertical direction. The pick-up head 121 may control fine movements in the vertical direction through the vertical moving apparatus.

The transfer mechanism CP may include a cushioning portion RP that directly contacts the die at a lower portion of the transfer mechanism CP and at least one hole TH penetrating the transfer mechanism CP to allow air communication. For example, the cushioning portion RP may include rubber to reduce impacts occurring between the die and the pick-up head 121.

The at least one hole TH may communicate with the through-hole VH to transmit changes in pressure generated by the hydraulic apparatus to the die. For example, when negative pressure is generated by the hydraulic apparatus, the transfer mechanism CP may transfer and secure the die. Conversely, when positive pressure is generated by the hydraulic apparatus, the transfer mechanism CP may apply pressure to the die to assist in the die attaching process and provide the die to the target object G for attachment.

Although a select number of pick-up heads are illustrated in the figures, it will be understood that this is provided as an example, and embodiments are not limited thereto. Accordingly, the number, size, arrangement of the pick-up heads may be varied.

In one or more embodiments, the controller 130 may be electrically connected to a driving unit configured to provide power for moving at least one pick-up head 121 along the head guide 110. The controller 130 may apply control signals to the driving unit to adjust the horizontal movement, vertical movement, and head pressure of at least one pick-up head 121. The head pressure may be the pressure applied to the die through at least one hole TH of the pick-up head 121. For example, the driving unit may include a hydraulic apparatus. The hydraulic apparatus may transfer the pressure generated therein to the pick-up head 121, thereby moving the pick-up head 121.

As described above, the die bonding apparatus 10 may include the die support device 20 disposed at the first position AR1, a die attachment device 30 disposed at the third position AR3 spaced apart in a horizontal direction from the first position AR1, and a head module 100 configured to transfer the die and circulate the die along an orbit between the first position AR1 and the third position AR3.

The head module 100 may include a head guide 110 arranged horizontally between the first position AR1 and the third position AR3 to provide a transfer route in the orbit and at least one pick-up head 121 movable along the transfer route of the head guide 110.

Accordingly, since the at least one pick-up head 121 may perform the pick-up operation and the attach operation within the same apparatus and within the same overall process, the process time may be reduced. Additionally, the at least one pick-up head 121 may move in a loop along the head guide 110, thereby increasing the accuracy of the process.

Hereinafter, a die bonding method using the die bonding apparatus of FIG. 1 will be described.

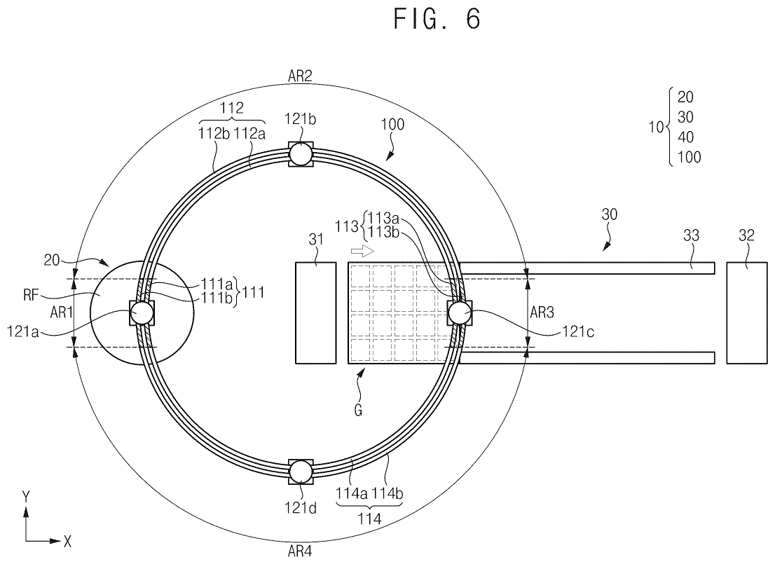

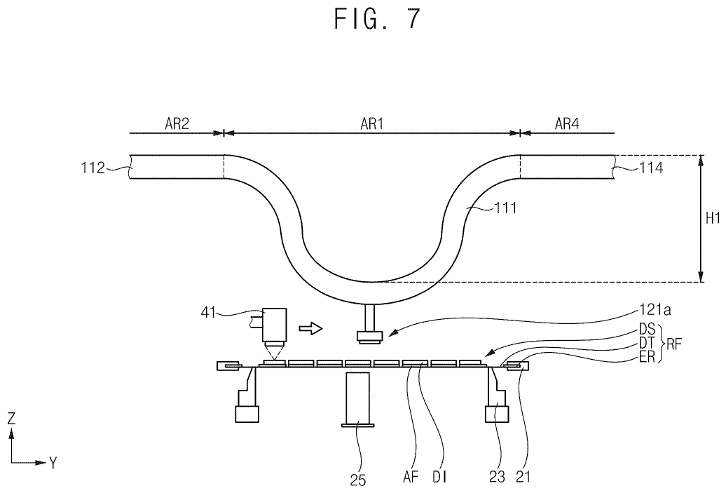

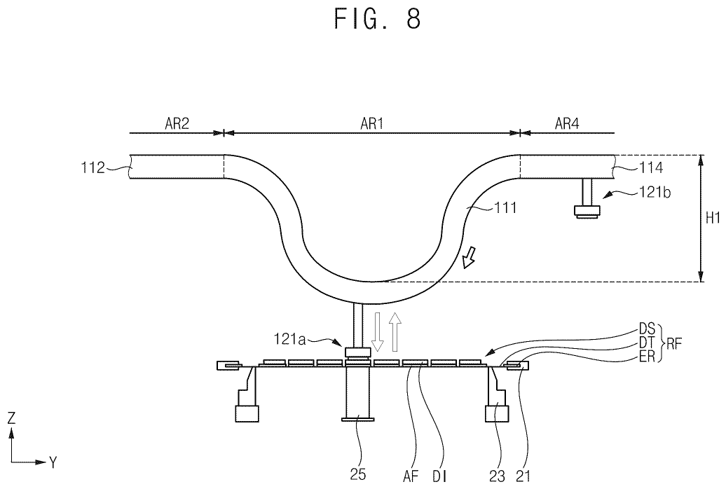

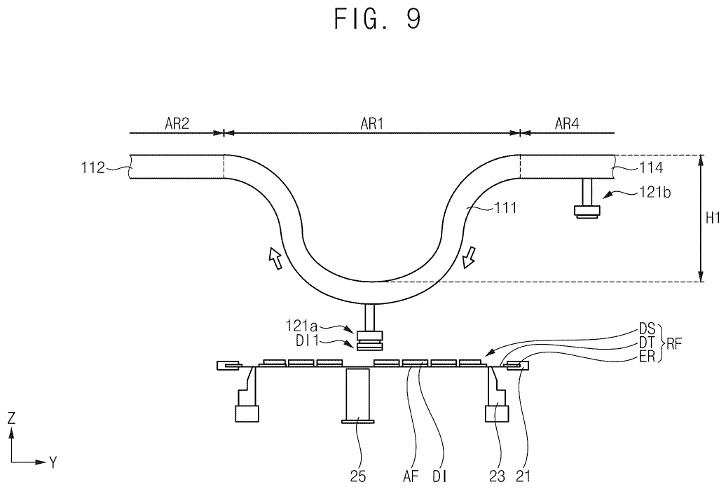

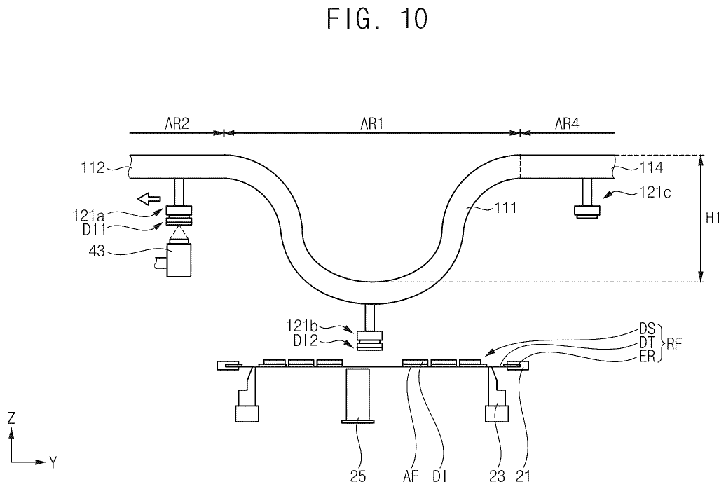

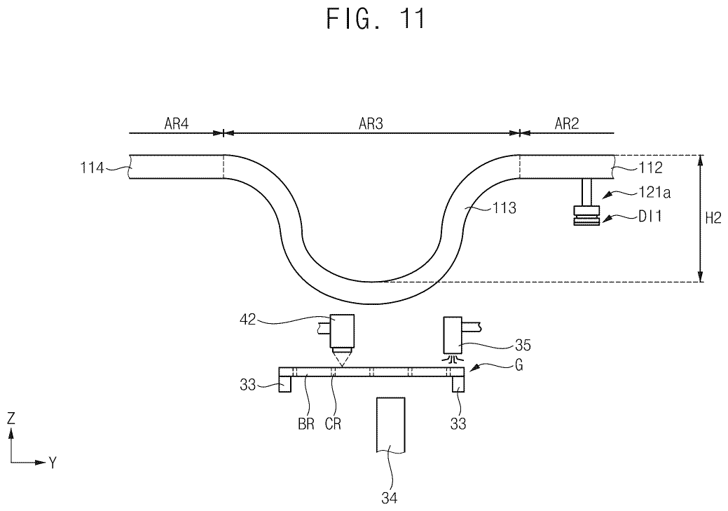

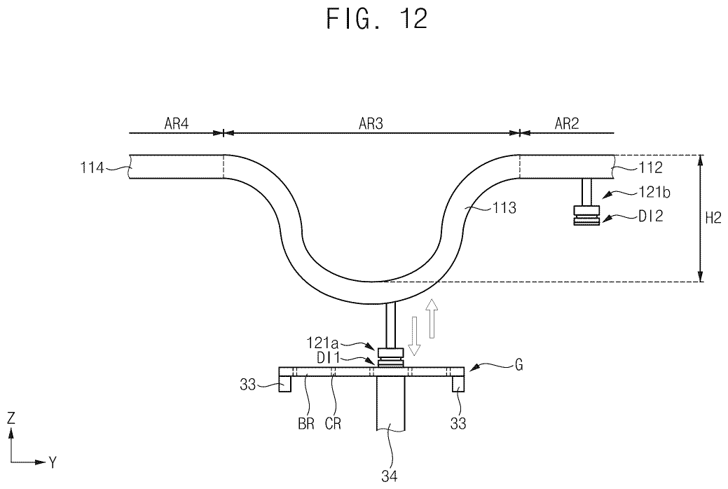

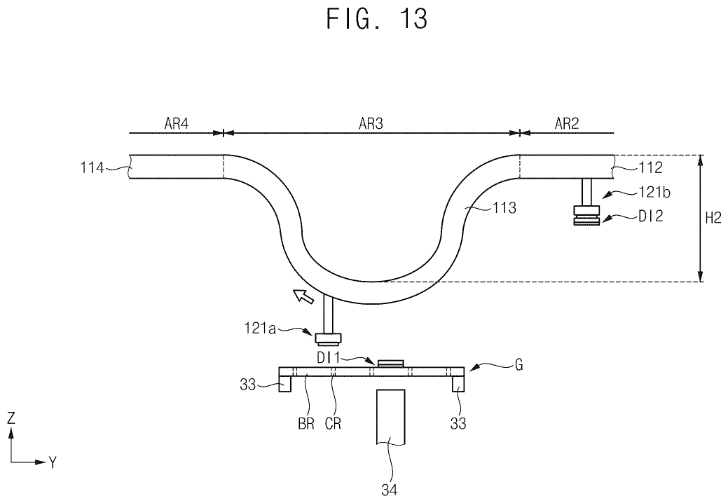

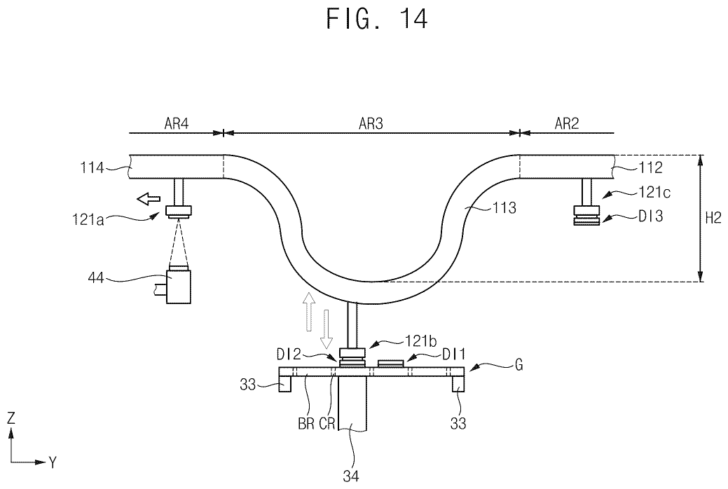

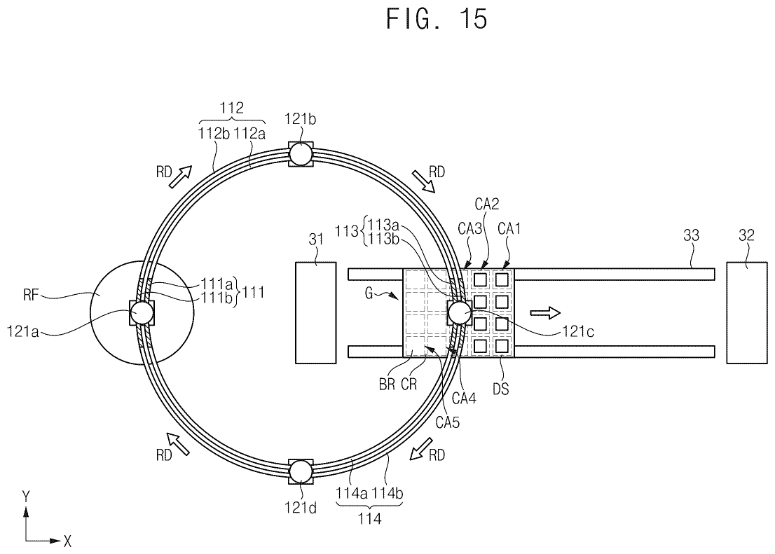

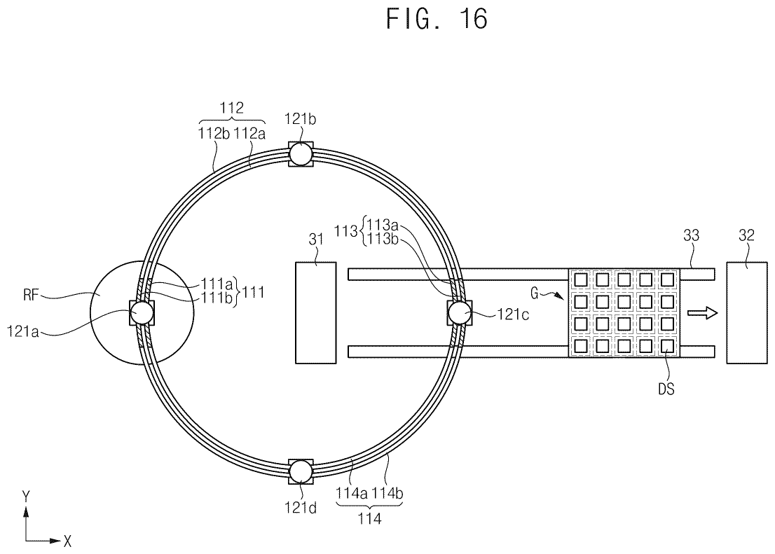

FIG. 6 is a plan view illustrating a substrate being loaded onto a die bonding apparatus according to one or more embodiments. FIGS. 7 to 9 are cross-sectional views illustrating a die being picked up using a die support device according to one or more embodiments. FIG. 10 is a cross-sectional view illustrating the first head moving to a die attachment device according to one or more embodiments. FIGS. 11 to 13 are cross-sectional views illustrating a die being bonded onto the substrate using a die attachment device according to one or more embodiments. FIG. 14 is a cross-sectional view illustrating the first head moving back to a die support device according to one or more embodiments. FIG. 15 is a plan view illustrating a plurality of dies being bonded onto the substrate using a die bonding apparatus according to one or more embodiments. FIG. 16 is a plan view illustrating the substrate being unloaded after the die bonding process is completed according to one or more embodiments.

Referring to FIG. 6, the die bonding apparatus 10 may be provided, and the target object G may be loaded from the loader 31 of the die attachment device 30. Thereafter, the first pick-up head 121a may be positioned at above the die support device 20.

In one or more embodiments, the die bonding apparatus 10 may include a die support device 20, a die attachment device 30, and a head module 100 configured to move the dies from the die support device 20 to the die attachment device 30.

A ring frame structure RF for supporting a wafer including a plurality of dies DS may be provided on the die support device 20.

In one or more embodiments, the die support device 20 may include a clamp 21 configured to clamp the ring frame structure RF that supports a wafer including diced dies, a support ring 23 configured to expand the ring frame structure RF, and a lift supporting mechanism 25 configured to support the dies being transferred.

The ring frame structure RF may include a dicing tape DT having elasticity to allow horizontal expansion, a plurality of dies DS provided on the dicing tape DT, and an expansion ring ER fixed to an edge region of the dicing tape DT.

Subsequently, the target object G may be loaded into the die attachment device 30. For example, the target object G may be loaded onto the substrate transfer mechanism 33 from the loader 31 of the die attachment device 30. Thereafter, the target object G may move in a first horizontal direction (X direction) by the substrate transfer mechanism 33.

In one or more embodiments, the die attachment device 30 may include a loader 31 for supplying the target object G, an unloader 32 for retrieving the target object G, and a substrate transfer mechanism 33 for moving the target object G from the loader 31 to the unloader 32 in the horizontal direction. Additionally, the die attachment device 30 may further include a heating apparatus 34 and a foreign substance removal apparatus 35.

For example, the target object G may be a substrate configured to mount a semiconductor device. Alternatively, the target object G may be another die. The die may be attached to another die to form a stacked die structure. The substrate may include a plurality of bonding regions BR and cutting region CR surrounding the plurality of bonding regions BR. For example, the bonding regions BR may be areas where the dies are attached. The bonding regions BR may be individualized into semiconductor packages by removing the cutting regions CR through a dicing process.

Thereafter, a head module 100 may be provided, and the first pick-up head 121a may move to the ring frame structure RF using the head module 100 such that the first pick-up head 121a is positioned above the ring frame structure RF.

In one or more embodiments, the head module 100 and may include a head guide 110 arranged horizontally between the first position AR1 and the third position AR3 to provide a transfer route and a die transfer device 120 movable along the transfer route of the head guide 110. The die transfer device 120 may include at least one pick-up head 121 movable along the transfer route of the head guide 110 and configured to pick up a die at the first position AR1 and attach the die to the target object G at the third position AR3. Additionally, the head module 100 may further include a controller 130 configured to control the at least one pick-up head 121.

The head guide 110 may be a rail that includes a plurality of portions. That is, the head guide 110 may include a rail having a pick-up rail portion 111, a supply rail portion 112, an attach rail portion 113, and a return rail portion 114 that are sequentially connected.

The die transfer device 120 may include at least one pick-up head 121 including first to fourth pick-up heads 121a, 121b, 121c, and 121d spaced apart from each other in a horizontal direction and along the orbital direction of the transfer route. Each of the first to fourth pick-up heads 121a, 121b, 121c, and 121d may perform the role of a transfer head and an attach head. For example, the transfer head may be a head configured to separate a die from the ring frame structure RF and transfer the die to the substrate. The attach head may be a head configured to position the die on the substrate and apply pressure to the die to attach it to the substrate.

Each of the first to fourth pick-up heads 121a, 121b, 121c, and 121d may sequentially move along the transfer route of the head guide 110 and perform the roles of the transfer head and the attach head. For example, each of the first to fourth pick-up heads 121a, 121b, 121c, and 121d may individually move along the transfer route of the head guide 110.

Referring to FIGS. 7 to 9, a plurality of dies DS may be captured by using the first camera 41, and the first die DI1 may be picked up by using the first pick-up head 121a.

The first camera 41 may be moved in a horizontal direction to capture the backside surfaces of the plurality of dies DS and check whether cracks have occurred in the plurality of dies DS.

The first pick-up head 121a may move downward by a first length H1 along the first vertical path of the pick-up rail portion 111 in the vertical direction, positioning the first pick-up head 121a above the first die DI1 among the plurality of dies DS. Subsequently, the vertical extension device VP of the first pick-up head 121a may move downward, and the transfer mechanism CP of the first pick-up head 121a may contact the first die DI1. Negative pressure may be applied through at least one hole VH of the transfer mechanism CP, transferring the first die DI1 to the cushioning portion RP of the transfer mechanism CP.

The lift supporting mechanism 25 may be positioned under the first die DI1, and the lift supporting mechanism 25 may lift the dicing tape DT beneath the first die DI1. Simultaneously, the vertical extension device VP of the first pick-up head 121a may move upward to separate the first die DI1 from the dicing tape DT.

Referring to FIG. 10, the first die DI1 may be moved to the die attachment device 30 of the die bonding apparatus 10 by using the first pick-up head 121a. Subsequently, the second pick-up head 121b may be positioned above the ring frame structure RF, and the second die DI2 may be picked up by using the second pick-up head 121b.

The first pick-up head 121a may move upward by a first length H1 along the first vertical path of the pick-up rail portion 111 and may be positioned on the supply rail portion 112. Thereafter, the first pick-up head 121a may move along the supply path of the supply rail portion 112 to position above the target object G. A backside surface of the first die DI1 may be inspected using the second camera 42, which captures an image of the first pick-up head 121a from below.

Additionally, the second pick-up head 121b may pick up the second die DI2 by using the die pick-up method described in FIGS. 7 to 9.

Referring to FIGS. 11 to 13, foreign substances on the target object G may be removed by using the foreign substance removal apparatus 35, the target object G may be captured by using the third camera 43, and the first die DI1 may be bonded onto the target object G by using the first pick-up head 121a.

The foreign substance removal apparatus 35 may be moved in a horizontal direction to release air onto the upper surface of the target object G, thereby removing foreign substances from the target object G.

The third camera 43 may be moved in a horizontal direction to capture images of the upper surface of the target object G and inspect circuit patterns of the target object G.

The first pick-up head 121a may move downward by a second length H2 along the second vertical path of the attach rail portion 113 in the vertical direction, positioning the first pick-up head 121a above the plurality of bonding regions BR. Thereafter, the vertical extension device VP of the first pick-up head 121a may move downward until the adhesive film AF of the first die DI1 contacts the target object G.

Additionally, the heating apparatus 34 may be positioned under the first die DI1, and heat may be applied to the bonding region BR located beneath the first die DI1 by using the heating apparatus 34. Simultaneously, positive pressure may be applied through at least one hole VH of the transfer mechanism CP to exert a pressing force on the first die DI1 in the vertical direction. Accordingly, the first die DI1 may be attached to the target object G by the adhesive film AF of the first die DI1.

Subsequently, the pressure applied to the first die DI1 by the first pick-up head 121a may be released, and the vertical extension device VP of the first pick-up head 121a may move upward to separate the first pick-up head 121a from the first die DI1.

Referring to FIG. 14, the first pick-up head 121a may return to the die support device 20 of the die bonding apparatus 10 along the return rail portion 114. The first pick-up head 121a may be captured by using the fourth camera 44.

The first pick-up head 121a may move upward by a first length H1 in the vertical direction along the second vertical path of the attach rail portion 113 to be positioned on the return rail portion 114. Thereafter, the first pick-up head 121a may move along the return path of the return rail portion 114 back to the ring frame structure RF such that the first pick-up head 121a is positioned above the ring frame structure RF. The first pick-up head 121a may be captured using the fourth camera 44 to inspect the condition of the first pick-up head 121a. Accordingly, a replacement cycle of the first pick-up head 121a may be predicted.

Additionally, the second pick-up head 121b may bond the second die DI2 onto the target object G by using the die bonding method described in FIGS. 11 to 13.

Referring to FIG. 15, the die bonding method described in FIGS. 7 to 14 may be repeated to bond a plurality of dies DS onto the plurality of bonding regions BR of the target object G.

At least one pick-up head 121 may be repeatedly moved along the head guide 110 to perform the die bonding method described in FIGS. 7 to 14.

The target object G may include a plurality of bonding regions BR arranged in multiple rows and columns. For example, the plurality of bonding regions BR may include a plurality of column arrays CA1, CA2, CA3, CA4, and CA5, where the bonding regions BR are sequentially arranged in the second horizontal direction (Y direction). The plurality of column arrays CA1, CA2, CA3, CA4, and CA5 may be sequentially arranged in the first horizontal direction (X direction).

By using the substrate transfer mechanism 33, the first column array CA1 of the target object G may be positioned under the attach rail portion 113. Thereafter, the die bonding method described in FIGS. 7 to 14 may be performed to attach dies onto the first column array CA1 of the target object G.

Subsequently, the substrate transfer mechanism 33 may move the target object G in the horizontal direction to position the second column array CA2 of the target object G under the attach rail portion 113. Thereafter, the die bonding method described in FIGS. 7 to 14 may be performed to attach dies onto the second column array CA2 of the target object G.

By using the substrate transfer mechanism 33, the target object G may be moved in the horizontal direction, and a plurality of dies DS may be attached onto the plurality of column arrays CA1, CA2, CA3, CA4, and CA5 of the target object G.

Referring to FIG. 16, the target object G, on which the die bonding process has been completed, may be unloaded by the unloader 32 of the die attachment device 30.

As described above, in the die bonding method, at least one pick-up head 121 may move along the head guide 110 and perform both picking up and attaching dies within the same apparatus and same process, thereby reducing the time consumed in the die bonding process. Additionally, in the die bonding method, at least one pick-up head 121 may move vertically along the first vertical path and the second vertical path provided by the head guide 110, further reducing the time consumed in the die bonding process.

Furthermore, in the die bonding method, at least one pick-up head 121 may move in an orbit (e.g., a loop of various shapes as described herein) along the head guide 110, which provides a transfer route in an orbit (e.g., an infinite loop), thereby increasing the accuracy of the process.

According to one or more embodiments, a die bonding apparatus may include a die support device disposed at a first position, a die attachment device disposed at a second position spaced apart in a horizontal direction from the first position, and a head module configured to transfer a die and circulate the die along an orbit between the first position and the second position.

The head module may include a head guide extending horizontally between the first position and the second position to provide a transfer route in the circular orbit and at least one pick-up head movable along the transfer route of the head guide.

Accordingly, since the at least one pick-up head may perform the pick-up operation and the attach operation simultaneously (e.g., within the same apparatus and the same process), the process time may be reduced. Additionally, the at least one pick-up head may move in a circular loop along the head guide, thereby increasing the accuracy of the process.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A die bonding apparatus, comprising:
a head guide extending in a horizontal direction between a first position and a second position, the head guide comprising an orbital transfer route comprising a supply path from the first position to the second position and a return path from the second position to the first position; and
a die transfer device configured to move along the orbital transfer route of the head guide, the die transfer device comprising at least one pick-up head configured to pick up a die at the first position and to attach the die on a target object at the second position.

2. The die bonding apparatus of claim 1, wherein the head guide comprises a rail comprising:
a supply rail portion providing the supply path;
a return rail portion providing the return path;
a pick-up rail portion extending in a vertical direction at the first position, the pick-up rail portion providing a first vertical movement path for the at least one pick-up head to pick up the die; and
an attach rail portion extending in the vertical direction at the second position, the attach rail portion providing a second vertical movement path for the at least one pick-up head to attach the die.

3. The die bonding apparatus of claim 2, wherein the pick-up rail portion and the attach rail portion are respectively between the supply rail portion and the return rail portion,
wherein the pick-up rail portion extends to a first predetermined height in the vertical direction from the supply rail portion, and
wherein the attach rail portion extends to a second predetermined height in the vertical direction from the return rail portion.

4. The die bonding apparatus of claim 1, further comprising:
a die support device under the head guide in a vertical direction and at the first position.

5. The die bonding apparatus of claim 4, wherein the die support device comprises:
a clamp configured to extend a ring frame structure that supports a wafer comprising the die;
a support ring configured to expand the ring frame structure; and
a lift supporting mechanism under the ring frame structure and configured to lift the die in the vertical direction.

6. The die bonding apparatus of claim 1, further comprising:
a die attachment device under the head guide in a vertical direction and at the second position.

7. The die bonding apparatus of claim 6, wherein the die attachment device comprises:
a loader configured to supply the target object;
an unloader configured to retrieve the target object; and
a substrate transfer mechanism configured to transfer the target object in the horizontal direction from the loader to the unloader.

8. The die bonding apparatus of claim 1, wherein the orbital transfer route of the head guide comprises a circular orbital path in plan view.

9. The die bonding apparatus of claim 1, wherein the at least one pick-up head comprises a plurality of heads sequentially arranged and spaced apart from each other along the transfer route, and
wherein the plurality of heads are configured to be movable between the first position and the second position.

10. The die bonding apparatus of claim 1, further comprising:
an imaging device comprising at least one camera configured to capture an image of the at least one pick-up head.

11. A die bonding apparatus, comprising:
a die support device at a first position and configured to provide a die;
a die attachment device at a second position spaced apart from the first position along a horizontal direction and configured to attach the die on a target object; and
a head module comprising a head guide horizontally extending between the first position and the second position and a die transfer device comprising a plurality of pick-up heads configured to move along the head guide,
wherein the head guide comprises an orbital transfer route comprising a supply path from the first position to the second position and a return path from the second position to the first position, and
wherein the plurality of pick-up heads are spaced apart from each other and each of the plurality of pick-up heads is configured to be individually movable along the transfer route of the head guide.

12. The die bonding apparatus of claim 11, wherein the head guide comprises a rail comprising:
a supply rail portion providing the supply path;
a return rail portion providing the return path;
a pick-up rail portion extending in a vertical direction at the first position, the pick-up rail portion providing a first vertical movement path for at least one of the plurality of pick-up heads to pick up the die; and
an attach rail portion extending in the vertical direction at the second position, the attach rail portion providing a second vertical movement path for at least one of the plurality of pick-up heads to attach the die.

13. The die bonding apparatus of claim 12, wherein the pick-up rail portion and the attach rail portion are respectively between the supply rail portion and the return rail portion,
wherein the pick-up rail portion extends to a first predetermined height in the vertical direction from the supply rail portion, and
wherein the attach rail portion extends to a second predetermined height in the vertical direction from the return rail portion.

14. The die bonding apparatus of claim 11, wherein the die support device comprises:
a clamp configured to extend a ring frame structure that supports a wafer comprising the die;
a support ring configured to expand the ring frame structure; and
a lift supporting mechanism under the ring frame structure and configured to lift the die in a vertical direction.

15. The die bonding apparatus of claim 11, wherein the die attachment device comprises:
a loader configured to supply the target object;
an unloader configured to retrieve the target object; and
a substrate transfer mechanism configured to transfer the target object in the horizontal direction from the loader to the unloader.

16. The die bonding apparatus of claim 15, wherein the die attachment device further comprises:
a heating apparatus under the target object and configured to transfer heat into the target object; and
a foreign substance removal apparatus above the target object and configured to discharge air onto the target object.

17. The die bonding apparatus of claim 11, wherein the orbital transfer route of the head guide comprises a circular orbital path in plan view.

18. The die bonding apparatus of claim 11, further comprising:
an imaging device comprising at least one camera configured to capture an image of at least one pick-up head among the plurality of pick-up heads.

19. The die bonding apparatus of claim 11, wherein each of the plurality of pick-up heads is configured to pick up the die at the first position and to attach the die on the target object at the second position.

20. A die bonding apparatus, comprising:
a die support device at a first position and configured to provide a die;
a die attachment device at a second position spaced apart from the first position along a horizontal direction and configured to attach the die on a target object;
a head guide extending in the horizontal direction between the first position and the second position, the head guide comprising an orbital transfer route comprising a supply path from the first position to the second position and a return path from the second position to the first position; and
a die transfer device configured to move along the transfer route of the head guide, the die transfer device comprising at least one pick-up head configured to pick up a die at the first position and to attach the die on the target object at the second position,
wherein the head guide further comprises a rail comprising:
a supply rail portion providing the supply path;
a return rail portion providing the return path;
a pick-up rail portion above the die support device, the pick-up rail portion providing a first vertical movement path extending in a vertical direction for the at least one pick-up head to pick up the die; and
an attach rail portion above the die attachment device, the attach rail portion providing a second vertical movement path extending in the vertical direction for the at least one pick-up head to attach the die.
